(19) United States
(12) Patent Application Publication
(10) Pub. No.: US 2021/0167172 A1
(43) Pub. Date: Jun. 3, 2021

(54) GRAPHENE SEMICONDUCTOR JUNCTION DEVICE

(71) Applicant: GWANGJU INSTITUTE OF SCIENCE AND TECHNOLOGY, Gwangju (KR)

(72) Inventors: Byoung Hun LEE, Gwangju (KR); So Young KIM, Gwangju (KR); Ki Yung KIM, Gwangju (KR)

(21) Appl. No.: 17/090,286

(22) Filed: Nov. 5, 2020

(30) Foreign Application Priority Data
Nov. 29, 2019 (KR) 10-2019-0157819

(51) Int. Cl. H01L 29/16; H01L 29/165; H01L 29/66; H01L 29/06; H01L 29/78; H01L 51/05

(52) U.S. Cl. CPC H01L 29/1606; H01L 29/165; H01L 51/0562; H01L 29/0684; H01L 29/78; H01L 29/66045

(57) ABSTRACT

A graphene semiconductor junction device, having a structure in which a graphene edge does not come into contact with a semiconductor, includes: a substrate; a gate electrode positioned on the substrate; a gate insulating layer that is positioned on the substrate to cover the gate electrode; a graphene layer positioned on the gate insulating layer; a semiconductor layer that is positioned on the graphene layer so as not to be joined to an edge of the graphene layer; a drain electrode positioned on the semiconductor layer; and a source electrode that is positioned on the graphene layer to be separated from the semiconductor layer.

### BACKGROUND OF THE INVENTION

### Field of the Invention

The present invention relates to a graphene semiconductor junction device, and more specifically, to a graphene semiconductor junction device having a structure in which a graphene edge does not come into contact with a semiconductor.

### Description of the Related Art

Graphene is a substance having two-dimensional hexagonal sp2-bonded carbon atoms and is reported to have interesting physical and electrical characteristics such as an electron behaving like a massless Dirac fermion and an anomalous hall effect at room temperature. In particular, a bandgap of the graphene is approximate to 0, and conduction and valence bands have a conic shape within a very small range of the Fermi level, and thereby a Schottky barrier is formed by a graphene/semiconductor heterojunction.

A graphene/semiconductor heterojunction device adjusts a barrier height by applying voltage to a gate electrode to change a graphene Fermi level and has a high current ratio of 10³ or higher, and thus the graphene/semiconductor heterojunction device is easily applied to a logic circuit.

However, when an edge of the graphene comes into contact with a semiconductor in the graphene/semiconductor heterojunction device as a switching device, a graphene edge-semiconductor contact portion acts as a Fermi level pinning site in the semiconductor, and an additional energy state is generated, and thus problems arise in that an On/Off ratio and a voltage level are lowered.

### CITATION LIST

### Patent Literature

Patent Literature 1: Korean Patent No. 2018-0052895

### SUMMARY OF THE INVENTION

According to an embodiment of the invention to solve problems of the related art described above, an object of the invention is to provide a graphene semiconductor junction device that can remarkably improve an On/Off ratio and a voltage level by having a structure in which a graphene edge does not come into contact with a semiconductor such that a Fermi level pinning site is not generated in the semiconductor and an additional energy state is not generated.

Technical objects to be achieved by the invention are not limited to the technical object mentioned above, and the following description enables additional unmentioned technical objects to be clearly understood by a person of ordinary skill in the art to which the invention belongs.

In order to achieve the technical objects, an embodiment of the invention provides a graphene semiconductor junction device including: a substrate; a gate electrode positioned on the substrate; a gate insulating layer that is positioned on the substrate to cover the gate electrode; a graphene layer positioned on the gate insulating layer; a semiconductor layer that is positioned on the graphene layer so as not to be joined to an edge of the graphene layer; a drain electrode positioned on the semiconductor layer; and a source electrode that is positioned on the graphene layer to be separated from the semiconductor layer.

The substrate is formed of any one of sapphire (Al₂O₃), ZnO, Si, GaAs, SiC, InO, SiO₂, or GaN.

Preferably, the gate electrode contains a metal or a conductive oxide.

Preferably, the semiconductor layer has a bottom area smaller than a top area of the graphene layer.

Preferably, the semiconductor layer has a structure to be joined only to a top surface of the graphene layer.

Preferably, the semiconductor layer is formed of any one material of ZnO, Si, Ge, DNTT, WS₂, WSe₂, or MoS₂.

Preferably, the source electrode or the drain electrode is electrically connected to an external device.

In order to achieve the technical objects, another embodiment of the invention provides a graphene semiconductor junction device including: a graphene layer; and a semiconductor layer that is joined to the graphene layer. An edge of the graphene layer does not have a surface which is joined to the semiconductor layer.

Preferably, the semiconductor layer has a bottom area smaller than a top area of the graphene layer.

Preferably, the semiconductor layer has a structure to be joined only to a top surface of the graphene layer.

Preferably, the semiconductor layer is formed of any one material of ZnO, Si, Ge, DNTT, WS₂, WSe₂, or MoS₂.

### BRIEF DESCRIPTION OF THE DRAWINGS

FIG. 1 is a sectional view illustrating a graphene semiconductor junction device of an embodiment of the invention;

FIG. 2 is a plan view illustrating the graphene semiconductor junction device of the embodiment of the invention;

FIG. 3 is a sectional view illustrating a graphene semiconductor junction device of another embodiment of the invention;

FIG. 4 is a sectional view illustrating a graphene semiconductor junction device having a graphene edge-semiconductor contact portion of the related art; and

FIGS. 5A-5C illustrates graphs indicating a gate voltage-drain current (FIG. 5A), an On/Off ratio (FIG. 5B), and a drain current (FIG. 5C) depending on a contact edge length of the graphene edge-semiconductor contact portion of the graphene semiconductor junction device in FIG. 4.

### DETAILED DESCRIPTION OF THE PREFERRED EMBODIMENTS

Hereinafter, the invention will be described with reference to the accompanying drawings. However, the invention can be realized as various different embodiments, thus not being limited to embodiments described here. Besides, a part irrelevant to the description is omitted from the drawings in order to clearly describe the invention, and similar reference signs are assigned to similar parts through the entire specification.

In the entire specification, a case where a certain part “is connected to (accesses, is in contact with, or is coupled to)” another part includes not only a case where the parts are “directly connected” to each other, but also a case where the parts are “indirectly connected” to each other with another member interposed therebetween. In addition, a case where a certain part “includes” a certain configurational element means that another configurational element is not excluded but can be further included, unless specifically described otherwise.

Terms used in this specification are only used to describe a specific embodiment and are not intentionally used to limit the invention thereto. A word having a singular form contain a meaning of its plural form, unless obviously implied otherwise in context. In this specification, words such as “to include” or “to have” are construed to specify that a feature, a number, a step, an operation, a configurational element, a member, or a combination thereof described in the specification is present and not to exclude presence or a possibility of addition of one or more additional features, numbers, steps, operations, configurational elements, members, or combinations thereof in advance.

Hereinafter, embodiments of the invention will be described in detail with reference to the accompanying drawings.

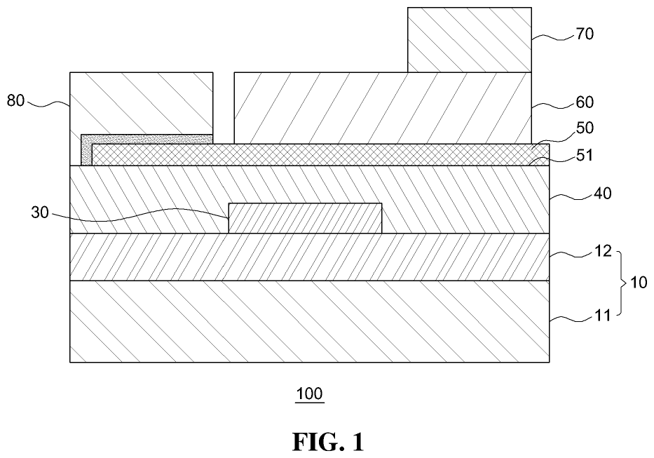

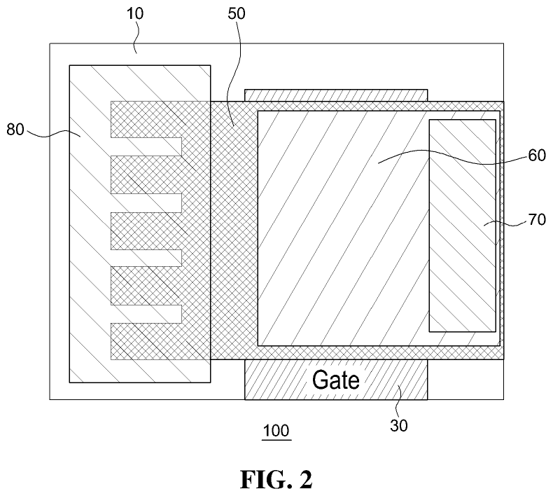

FIG. 1 is a sectional view illustrating a graphene semiconductor junction device 100 of an embodiment of the invention, and FIG. 2 is a plan view illustrating the graphene semiconductor junction device 100 of the embodiment of the invention.

As illustrated in FIGS. 1 and 2, the graphene semiconductor junction device 100 can be configured of a switching device including a substrate 10 formed by a lower substrate 11 and an upper substrate 12; a gate electrode 30 positioned on the substrate 10; a gate insulating layer 40 formed of a dielectric that is positioned on the substrate 10 to cover the gate electrode 30, a graphene layer 50 positioned on the gate insulating layer 40, a semiconductor layer 60 that is positioned on the graphene layer 50 so as not to be joined to an edge 51 of the graphene layer 50, a drain electrode 70 positioned on the semiconductor layer 60, and a source electrode 80 that is positioned on the graphene layer 50 to be separated from the semiconductor layer 60.

Examples of a material of the substrate which configures the graphene semiconductor junction device 100 can include sapphire (Al₂O₃), ZnO, Si, GaAs, SiC, InO, SiO₂, or GaN.

The gate electrode 30 can be made of a metal or a conductive oxide.

The semiconductor layer 60 has a bottom area smaller than a top area of the graphene layer 50 such that an underside of the semiconductor layer 60 is positioned in a top surface of the graphene layer 50, and thereby the semiconductor layer is configured not to come into contact with the graphene edge 51. The semiconductor layer 60 has a structure to be joined only to the top surface of the graphene layer 50.

At that point, the semiconductor layer can be formed of any one material of ZnO, Si, Ge, DNTT, WS₂, WSe₂, or MoS₂.

The source electrode 80 or the drain electrode 70 is laminated to be electrically connected to an external device.

Meanwhile, the present invention may be applied to the opposite structure of the graphene semiconductor junction device of FIGS.1 and 2.

For example, the graphene semiconductor junction device according to an embodiment of the present invention can be configured of a switching device including a semiconductor layer; a graphene layer positioned on the semiconductor layer; a gate insulating layer positioned on the graphene layer; and a gate electrode positioned on the gate insulating layer, wherein the semiconductor layer has a structure positioned so as not to be joined to an edge of the graphene layer. For example, the semiconductor layer has a structure to be joined only to the bottom surface of the graphene layer.

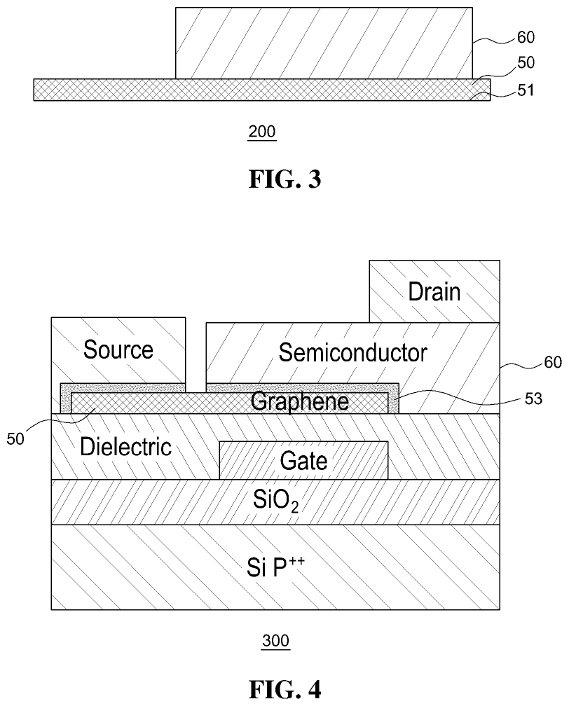

FIG. 3 is a sectional view illustrating a graphene semiconductor junction device 200 of another embodiment of the invention.

As illustrated in FIG. 3, the graphene semiconductor junction device 200 of the other embodiment of the invention includes a graphene layer 50 and a semiconductor layer 60 that is joined to the graphene layer 50. An edge 51 of the graphene layer 50 is laminated to have a structure in which the edge does not have a surface which is joined to the semiconductor layer 60.

The graphene semiconductor junction device 200 in FIG. 3 has a configuration in which the semiconductor layer 60 has a bottom area smaller than a top area of the graphene layer 50 such that the edge 51 of the graphene layer 50 is not joined to the semiconductor layer 60. In other words, the semiconductor layer 60 has a structure to be joined only to the top surface of the graphene layer 50.

The semiconductor layer can be laminated and formed of any one material of ZnO, Si, Ge, DNTT (dinaphtho[2,3-b:2′,3′-f]thieno[3,2-b]thiophene), WS₂, WSe₂, or MoS₂.

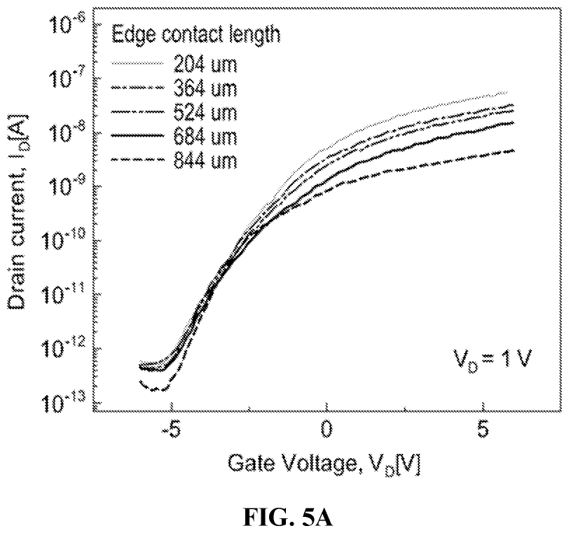

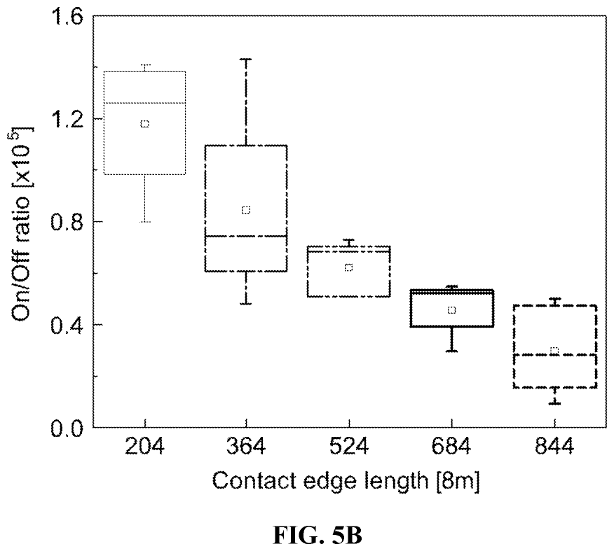

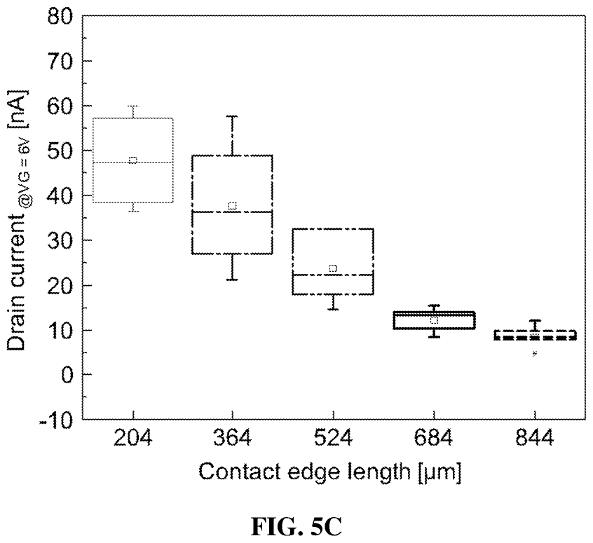

FIG. 4 is a sectional view illustrating a graphene semiconductor junction device 300 having a graphene edge-semiconductor contact portion 53 of the related art, and FIGS. 5A-5C illustrates graphs indicating a gate voltage-drain current (a), an On/Off ratio (b), and a drain current (c) depending on a contact edge length of the graphene edge-semiconductor contact portion 53 of the graphene semiconductor junction device 300 in FIG. 4.

As illustrated in FIGS. 4 and 5A-5C, in a case of the graphene semiconductor junction device 300 having the graphene edge-semiconductor contact portion 53 of the related art, as the contact edge length of the graphene edge-semiconductor contact portion 53 increases, measurement values of the drain current (a) according to gate-voltage, the On/Off ratio (b), and the drain current (c) are all decreased, as illustrated in FIGS. 5A-5C.

However, in the case of the graphene semiconductor junction device (100 or 200) of the embodiment of the invention, the graphene edge-semiconductor contact portion 53 is not formed, and thus a Fermi level pinning site is not formed such that a phenomenon of a decrease in the drain current (a) according to the gate-voltage, the On/Off ratio (b), and the drain current (c) as illustrated in FIGS. 5A-5C do not occur.

According to embodiments of the invention, a graphene semiconductor junction device has effects of remarkably improving an On/Off ratio and a voltage level by having a structure in which a graphene edge does not come into contact with a semiconductor such that a Fermi level pinning site is not generated in the semiconductor and an additional energy state is not generated.

The effects of the invention are construed not to be limited to the above-mentioned effects but to include every effect that can be derived from the configurations of the invention described in the detailed description of the embodiments or claims of the invention.

The description of the invention described above is provided as an example, and a person of ordinary skill in the art to which the invention belongs can understand that it is possible to easily modify the invention to another embodiment without changing the technical idea or an essential feature of the invention. Therefore, the embodiments described above need to be understood as exemplified embodiments in every aspect and not as embodiments to limit the invention. For example, configurational elements described in a singular form can be realized in a distributed manner. Similarly, the configurational elements described in the distributed manner can be realized in a combined manner.

The scope of the invention needs to be represented by the claims to be described below, and meaning and the scope of the claims and every modification or modified embodiment derived from an equivalent concept of the claims need to be construed to be included in the scope of the invention.

### REFERENCE SIGNS LIST

100, 200, 300: graphene semiconductor junction device
10: substrate
11: lower substrate
12: upper substrate (SiO₂)
30: gate electrode
40: gate insulating layer
50: graphene layer
51: edge(graphene edge)
53: graphene edge-semiconductor contact portion
60: semiconductor layer
70: drain electrode
80: source electrode

What is claimed is:

1. A graphene semiconductor junction device comprising:
a substrate;
a gate electrode positioned on the substrate;
a gate insulating layer that is positioned on the substrate to cover the gate electrode;
a graphene layer positioned on the gate insulating layer;
a semiconductor layer that is positioned on the graphene layer so as not to be joined to an edge of the graphene layer;
a drain electrode positioned on the semiconductor layer; and
a source electrode that is positioned on the graphene layer to be separated from the semiconductor layer.

2. The graphene semiconductor junction device according to claim 1,
wherein the substrate is formed of any one material of sapphire Al₂O₃, ZnO, Si, GaAs, SiC, InO, SiO₂, or GaN.

3. The graphene semiconductor junction device according to claim 1,
wherein the gate electrode contains a metal or a conductive oxide.

4. The graphene semiconductor junction device according to claim 1,
wherein the semiconductor layer has a bottom area smaller than a top area of the graphene layer.

5. The graphene semiconductor junction device according to claim 1,
wherein the semiconductor layer has a structure to be joined only to a top surface of the graphene layer.

6. The graphene semiconductor junction device according to claim 1,
wherein the semiconductor layer is formed of any one material of ZnO, Si, Ge, DNTT, WS₂, WSe₂, or MoS₂.

7. The graphene semiconductor junction device according to claim 1,
wherein the source electrode or the drain electrode is electrically connected to an external device.

8. A graphene semiconductor junction device comprising:
a graphene layer; and
a semiconductor layer that is joined to the graphene layer,
wherein an edge of the graphene layer does not have a surface which is joined to the semiconductor layer.

9. The graphene semiconductor junction device according to claim 8,
wherein the semiconductor layer has a bottom area smaller than a top area of the graphene layer.

10. The graphene semiconductor junction device according to claim 8,
wherein the semiconductor layer has a structure to be joined only to a top surface of the graphene layer.

11. The graphene semiconductor junction device according to claim 8,
wherein the semiconductor layer is formed of any one material of ZnO, Si, Ge, DNTT, WS₂, WSe₂, or MoS₂ to be laminated.
